(19) United States
(12) Patent Application Publication
(10) Pub. No.: US 2024/0290716 A1
(43) Pub. Date: Aug. 29, 2024

(54) SUPPORT SUBSTRATE, MANUFACTURING METHOD OF SUPPORT SUBSTRATE, AND MANUFACTURING METHOD OF SEMICONDUCTOR STORAGE DEVICE

(71) Applicant: Kioxia Corporation, Tokyo (JP)

(72) Inventor: Masayoshi TAGAMI, Kuwana (JP)

(73) Assignee: Kioxia Corporation, Tokyo (JP)

(21) Appl. No.: 18/586,767

(22) Filed: Feb. 26, 2024

(30) Foreign Application Priority Data
Feb. 28, 2023 (JP) 2023-029939

(51) Int. Cl. H01L 23/528; H01L 21/768; H01L 23/522; H10B 41/27; H10B 41/40; H10B 43/27; H10B 43/40

(52) U.S. Cl. CPC H01L 23/5283; H01L 21/76897; H01L 23/5226; H10B 41/27; H10B 41/40; H10B 43/27; H10B 43/40

(57) ABSTRACT

A support substrate according to an embodiment includes: a substrate having conductivity; a first insulating layer disposed on the substrate; a first layer having conductivity and disposed on the first insulating layer; a second insulating layer disposed on the first layer; a second layer having conductivity and disposed on the second insulating layer; a plurality of first plugs penetrating the first insulating layer and connecting the substrate and the first layer; and a plurality of second plugs penetrating the second insulating layer and connecting the first layer and the second layer.

### CROSS-REFERENCE TO RELATED APPLICATIONS

This application is based upon and claims the benefit of priority from Japanese Patent Application No. 2023-029939, filed on Feb. 28, 2023; the entire contents of which are incorporated herein by reference.

### FIELD

Embodiments described herein relate generally to a support substrate, a manufacturing method of a support substrate, and a manufacturing method of a semiconductor storage device.

### BACKGROUND

Semiconductor storage devices or the like may be configured by bonding a support substrate on which a plurality of memory pillars is formed and a semiconductor substrate on which a peripheral circuit is formed. After the bonding with the semiconductor substrate, the support substrate is peeled off and reused. By repeatedly reusing the support substrate, the manufacturing cost of the semiconductor storage devices and the like can be reduced.

However, the support substrate is worn at the time of peeling off. In addition, for example, in order to suppress arcing at the time of forming a memory pillar using plasma etching or the like, a plug electrically connected with the memory pillar may be formed on a support substrate. By forming the plug, the wear of the support substrate at the time of peeling off is further accelerated.

### BRIEF DESCRIPTION OF THE DRAWINGS

FIG. 1 is a cross-sectional view illustrating a schematic structure example of a semiconductor storage device according to an embodiment;

FIGS. 2A and 2B are diagrams illustrating an example of a structure of the semiconductor storage device according to the embodiment;

FIGS. 3A and 3B are diagrams illustrating an example of a structure of a support substrate used for manufacture of the semiconductor storage device according to the embodiment;

FIGS. 4A to 4D are enlarged cross-sectional views illustrating an example of a part of a procedure of a manufacturing method of a support substrate according to the embodiment;

FIGS. 5A to 5C are cross-sectional views sequentially illustrating an example of a part of the procedure of the manufacturing method of the semiconductor storage device according to the embodiment;

FIGS. 6A to 6C are cross-sectional views sequentially illustrating an example of a part of the procedure of the manufacturing method of the semiconductor storage device according to the embodiment;

FIGS. 7A and 7B are cross-sectional views sequentially illustrating an example of a part of the procedure of the manufacturing method of the semiconductor storage device according to the embodiment;

FIGS. 8A and 8B are cross-sectional views sequentially illustrating an example of a part of the procedure of the manufacturing method of the semiconductor storage device according to the embodiment;

FIGS. 9A and 9B are cross-sectional views sequentially illustrating an example of a part of the procedure of the manufacturing method of the semiconductor storage device according to the embodiment;

FIGS. 10A and 10B are cross-sectional views sequentially illustrating an example of a part of the procedure of the manufacturing method of the semiconductor storage device according to the embodiment;

FIGS. 11A and 11B are cross-sectional views sequentially illustrating an example of a part of the procedure of the manufacturing method of the semiconductor storage device according to the embodiment;

FIGS. 12A and 12B are cross-sectional views sequentially illustrating an example of a part of the procedure of the manufacturing method of the semiconductor storage device according to the embodiment;

FIGS. 13A and 13B are cross-sectional views sequentially illustrating an example of a part of the procedure of the manufacturing method of the semiconductor storage device according to the embodiment;

FIGS. 14A and 14B are cross-sectional views sequentially illustrating an example of a part of the procedure of the manufacturing method of the semiconductor storage device according to the embodiment;

FIG. 15 is a cross-sectional view sequentially illustrating an example of a part of the procedure of the manufacturing method of the semiconductor storage device according to the embodiment;

FIG. 16 is a cross-sectional view sequentially illustrating an example of a part of the procedure of the manufacturing method of the semiconductor storage device according to the embodiment;

FIGS. 17A and 17B are cross-sectional views sequentially illustrating an example of a part of the procedure of the manufacturing method of the semiconductor storage device according to the embodiment;

FIGS. 18A to 18C are cross-sectional views illustrating an example of a part of a procedure of reproduction processing of the support substrate according to the embodiment;

FIGS. 19A and 19B are partially enlarged cross-sectional views illustrating a state in which a support substrate according to a comparative example is peeled off; and

FIGS. 20A to 20E are diagrams illustrating examples of a structure of a plug of a support substrate according to the embodiment and a modification of the embodiment.

### DETAILED DESCRIPTION

A support substrate according to an embodiment includes: a substrate having conductivity; a first insulating layer disposed on the substrate; a first layer having conductivity and disposed on the first insulating layer; a second insulating layer disposed on the first layer; a second layer having conductivity and disposed on the second insulating layer; a plurality of first plugs penetrating the first insulating layer and connecting the substrate and the first layer; and a plurality of second plugs penetrating the second insulating layer and connecting the first layer and the second layer.

Hereinafter, embodiments of the present invention will be described in detail with reference to the drawings. Note that the present invention is not limited by the following embodiments. In addition, components in the following embodiments include those that can be easily conceived by those skilled in the art or those that are substantially the same.

### (Configuration Example of Semiconductor Storage Device)

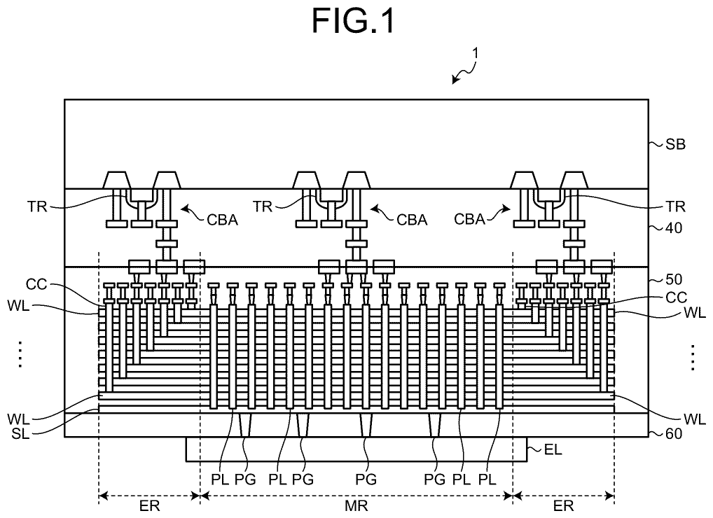

FIG. 1 is a cross-sectional view illustrating a schematic structure example of a semiconductor storage device 1 according to an embodiment. Note that hatching is omitted in FIG. 1 in consideration of readability of the drawing.

As illustrated in FIG. 1, the semiconductor storage device 1 includes an electrode film EL, a source line SL, and a plurality of word lines WL in order from the lower side of the drawing. The semiconductor storage device 1 further includes peripheral circuits CBA provided on a semiconductor substrate SB above the plurality of word lines WL.

The source line SL is disposed over the electrode film EL via an insulating layer 60. A plurality of plugs PG is arranged in the insulating layer 60, and the source line SL and the electrode film EL maintain electrical conduction via the plugs PG. As a result, a source potential can be applied to the source line SL from the outside of the semiconductor storage device 1 via the electrode film EL and the plugs PG.

The plurality of word lines WL is stacked on the source line SL. A memory region MR is disposed at the center of the plurality of word lines WL, and contact regions ER are arranged at both ends of the plurality of word lines WL.

In the memory region MR, pillars PL, as a plurality of memory pillars, penetrating the word lines WL in a stacking direction are arranged. A plurality of memory cells is formed at intersections of the pillars PL and the word lines WL. As a result, the semiconductor storage device 1 is configured as, for example, a three-dimensional nonvolatile memory in which memory cells are three-dimensionally arranged in the memory region MR.

In a contact region ER, a plurality of contacts CC each connected with one of the plurality of word lines WL is arranged. Note that, in the present specification, in the extending direction of the contacts CC, the connection end side of the contacts CC with the word lines WL is referred to as a lower side of the semiconductor storage device 1.

From a contact CC, a write voltage, a read voltage, and the like are applied to a memory cell included in the memory region MR at the center of the plurality of word lines WL via a word line WL at the same height position as that of the memory cell. In this manner, the word lines WL stacked in multiple layers are individually drawn out by these contacts CC.

The plurality of word lines WL, pillars PL, and contacts CC are covered with an insulating layer 50. The insulating layer 50 also extends around the plurality of word lines WL.

The semiconductor substrate SB above the insulating layer 50 is, for example, a silicon substrate. The peripheral circuits CBA including a transistor TR, wiring, and others are arranged on a surface of the semiconductor substrate SB. Various voltages applied from the contacts CC to the memory cells are controlled by the peripheral circuits CBA electrically connected with the contacts CC. In this manner, the peripheral circuits CBA control the electrical operation of the memory cells.

The peripheral circuits CBA are covered with the insulating layer 40, and the insulating layer 40 and the insulating layer 50 covering the stacked body LM are joined to each other, thereby forming the semiconductor storage device 1 including the structure of the plurality of word lines WL, pillars PL, contacts CC, and others and the peripheral circuits CBA.

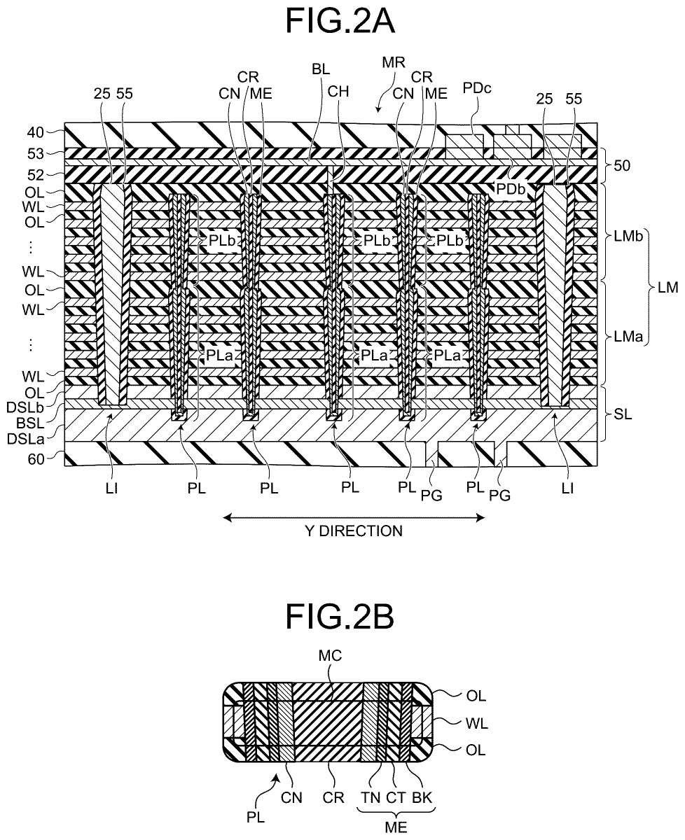

Next, a detailed structure example of the semiconductor storage device 1 will be described with reference to FIGS. 2A and 2B. FIGS. 2A and 2B are diagrams illustrating an example of the structure of the semiconductor storage device 1 according to the embodiment.

More specifically, FIG. 2A is a cross-sectional view along a Y direction illustrating an example of the structure of the memory region MR. FIG. 2B is an enlarged cross-sectional view at a height position of a word line WL of a pillar PL disposed in the memory region MR. However, in FIG. 2A, structures of a lower portion of the insulating layer 60 and an upper portion of the insulating layer 40 are omitted.

Incidentally, herein, both an X direction and the Y direction extend in directions of surfaces of the word lines WL, and the X direction and the Y direction are orthogonal to each other. In addition, an electrical drawing direction of a word line WL may be referred to as a first direction, and the first direction is the X direction. In addition, a direction intersecting the first direction may be referred to as a second direction, and the second direction is the Y direction. However, since the semiconductor storage device 1 may include a manufacturing error, the first direction and the second direction are not necessarily orthogonal to each other.

As illustrated in FIG. 2A, the source line SL has a multilayer structure in which, for example, a lower source line DSLa, a middle source line BSL, and an upper source line DSLb are stacked in this order on the insulating layer 60.

The lower source line DSLa, the middle source line BSL, and the upper source line DSLb are, for example, polysilicon layers. Among them, at least the middle source line BSL may be a conductive polysilicon layer or the like in which an impurity is diffused.

The stacked body LM is disposed on the source line SL. The stacked body LM includes stacked bodies LMa and LMb in which a plurality of word lines WL and a plurality of insulating layers OL are alternately stacked layer by layer. The stacked body LMa is disposed on the source line SL, and the stacked body LMb is disposed on the stacked body LMa.

One or more select gate lines may be further arranged below the lowermost word line WL of the stacked body LMa. In addition, one or more select gate lines may be further arranged on the uppermost word line WL of the stacked body LMb. The numbers of stacked layers of the word lines WL, the select gate lines, and others in the stacked body LM may be any number and ranges, for example, from several tens to several hundreds of layers.

The plurality of word lines WL is, for example, tungsten layers or molybdenum layers. The plurality of insulating layers OL are, for example, silicon oxide layers or the like.

The uppermost insulating layer OL of each of the stacked bodies LMa and LMb is thicker than, for example, the other insulating layers OL in the stacked bodies LMa and LMb. The uppermost insulating layer OL of the stacked body LMa is in contact with the lowermost word line WL of the stacked body LMb, and insulating layers 52 and 53 are arranged in this order on the uppermost insulating layer OL of the stacked body LMb. The insulating layers 52 and 53 constitute a part of the insulating layer 50 described above, and the upper surface of the insulating layer 53 is in contact with the lower surface of the insulating layer 40 on the peripheral circuits CBA side.

The stacked body LM is divided in the Y direction by a plurality of plate-shaped contacts LI.

That is, the plate-shaped contacts LI are arranged in the Y direction and each extend in the stacking direction of the stacked body LM and the X direction. As described above, a plate-shaped contact LI continuously extends inside the stacked body LM from one end to the other end of the stacked body LM in the X direction. Moreover, a plate-shaped contact LI penetrates the stacked body LM and the upper source line DSLb and reaches the middle source line BSL.

Each of the plate-shaped contacts LI includes insulating layers 55 and a conductive layer 25. The insulating layers 55 are, for example, silicon oxide layers or the like. The conductive layer 25 is, for example, a tungsten layer or a conductive polysilicon layer.

The insulating layers 55 cover the side walls facing each other in the Y direction of the plate-shaped contact LI. Conductive layer 25 is filled inside the insulating layers 55 and is electrically connected to the source line SL including the middle source line BSL. In addition, the conductive layer 25 is connected with upper layer wiring in a cross section different from that in FIG. 2A. With such a structure, the plate-shaped contact LI functions as a source line contact.

However, instead of the plate-shaped contacts LI, plate-shaped members each filled with an insulating layer may penetrate the stacked body LM and extend in a direction along the X direction, thereby dividing the stacked body LM in the Y direction. In this case, such plate-shaped members do not have a function as a source line contact.

In the memory region MR of the stacked body LM, the plurality of pillars PL, penetrating the stacked body LM, the upper source line DSLb, and the middle source line BSL and reaching the lower source line DSLa, is dispersedly arranged.

The plurality of pillars PL has, for example, a staggered arrangement when viewed from the stacking direction of the stacked body LM. Each pillar PL has, for example, a circular shape, an elliptical shape, an oval shape, or the like in a cross section in a direction along the layer direction of the stacked body LM, namely, in a direction along an XY plane.

A pillar PL includes a pillar PLa that penetrates the stacked body LMa from the uppermost insulating layer OL of the stacked body LMa and reaches the source line SL and a pillar PLb that penetrates the stacked body LMb from the uppermost insulating layer OL of the stacked body LMb, reaches the uppermost insulating layer OL of the stacked body LMa, and is connected to an upper end of a corresponding pillar PLa.

Each of the plurality of pillars PL includes a memory layer ME extending in the stacked body LM in the stacking direction, a channel layer CN penetrating the stacked body LM and connected to the middle source line BSL, and a core layer CR serving as a core material of the pillar PL.

The memory layer ME is disposed on a side surface of the pillar PL excluding the depth position of the middle source line BSL. Moreover, the memory layer ME is also disposed on the bottom surface of the pillar PL reaching the depth of the lower source line DSLa.

The channel layer CN is on the inner side of the memory layer ME, penetrates the stacked body LM, the upper source line DSLb, and the middle source line BSL, and reaches the depth of the lower source line DSLa. That is, the channel layer CN is disposed on the side surface and the bottom surface of the pillar PL via the memory layer ME. The core layer CR is filled further inside the channel layer CN.

However, a part of the channel layer CN is in contact with middle source line BSL on the side surface and is thereby electrically connected to the source line SL that includes the middle source line BSL. Furthermore, the upper end of the channel layer CN is connected with a bit line BL extending in a direction along the Y direction in the insulating layer 53 via a plug CH disposed in the insulating layer 52.

As illustrated in FIG. 2B, the memory layer ME has a multilayer structure in which a block insulating layer BK, a charge accumulation layer CT, and a tunnel insulating layer TN are stacked in this order from an outer circumferential side of the pillar PL.

The block insulating layer BK and the tunnel insulating layer TN of the memory layer ME and the core layer CR are, for example, silicon oxide layers or the like. The charge accumulation layer CT of the memory layer ME is, for example, a silicon nitride layer or the like. The channel layer CN is, for example, a semiconductor layer such as a polysilicon layer or an amorphous silicon layer.

As illustrated in FIG. 2B, with the above structure, memory cells MC are formed at portions facing individual word lines WL on the side surfaces of the pillars PL. With a predetermined voltage applied from a word line WL, data is written to and read from a memory cell MC.

Furthermore, in a case where the stacked body LM includes select gate lines, select gates are formed at portions facing the select gate lines on side surfaces of the pillars PL. With a predetermined voltage applied from the select gate lines, the select gates are turned on or off, and memory cells MC formed in the pillars PL to which these select gates belong are brought into a selected state or a non-selected state.

The voltage from the word line WL or others to the memory cell MC or others is applied via the above-described contact CC (see FIG. 1) electrically connected to the above-described peripheral circuit CBA (see FIG. 1) and penetrating the stacked body LM to reach each word line WL.

In addition, data from the memory cell MC is read out to a bit line BL connected to the pillar PL. The bit line BL is connected to an electrode pad PDb disposed on a surface of the insulating layer 53. The electrode pad PDb is connected to an electrode pad PDc disposed on a surface of the insulating layer 40 and is electrically connected to a peripheral circuit CBA. As a result, the data of the memory cell MC read out to the bit line BL is processed by the peripheral circuit CBA.

### (Manufacturing Method of Semiconductor Storage Device)

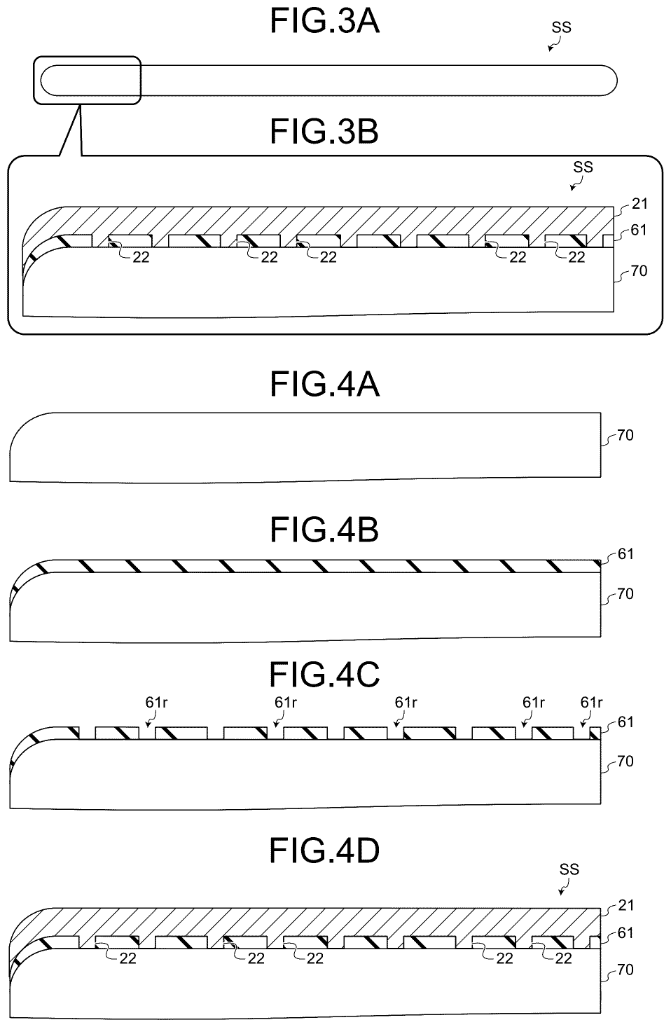

Next, a manufacturing method of the semiconductor storage device 1 according to the embodiment will be described with reference to FIGS. 3A to 18C. Note that the manufacturing method of the semiconductor storage device 1 partially includes a manufacturing method of a support substrate SS.

First, illustrated in FIGS. 3A to 4D are the support substrate SS that supports the semiconductor storage device 1 during manufacture and a state in which the support substrate SS is manufactured.

FIGS. 3A and 3B are diagrams illustrating an example of a structure of the support substrate SS used for manufacture of the semiconductor storage device 1 according to the embodiment. More specifically, FIG. 3A is a diagram illustrating the entire support substrate SS, and FIG. 3B is a partially enlarged cross-sectional view of the support substrate SS.

As illustrated in FIGS. 3A and 3B, the support substrate SS includes a substrate 70, an insulating layer 61, a sacrificial layer 21, and a plurality of plugs 22.

The substrate 70 is a semiconductor substrate such as a silicon substrate or a conductive substrate such as a metal substrate or a sapphire substrate and has at least predetermined conductivity.

The insulating layer 61 as a first insulating layer is, for example, a silicon oxide layer or the like and is disposed on the upper surface of the substrate 70. A layer thickness of the insulating layer 61 is, for example, within a range between 30 nm and 100 nm and, more preferably within a range between 50 nm and 60 nm.

The sacrificial layer 21 as the first layer is disposed on the insulating layer 61, is a semiconductor layer such as a polysilicon layer or an amorphous silicon layer or a conductive layer such as a metal layer, and has at least predetermined conductivity. A layer thickness of the sacrificial layer 21 is, for example, within a range between 300 nm and 700 nm.

The plugs 22 as a plurality of first plugs are dispersedly arranged in the insulating layer 61. Each plug 22 has a columnar shape, for example, and penetrates the insulating layer 61 to electrically connect the sacrificial layer 21 and the substrate 70 arranged above and below the insulating layer 61.

When viewed from the stacking direction of the insulating layer 61 and the sacrificial layer 21, the area of the plurality of plugs 24 is preferably greater than or equal to 50% of the area of an arrangement region of the insulating layer 61. That is, in a case where the plurality of plugs 24 is not arranged, the area occupied by the insulating layer 61 can be set to 100%, and the area of the plurality of plugs 24 with respect to this can be set to greater than or equal to 50%. The area of the insulating layer 61 in a case where the plurality of plugs 24 is not arranged is substantially equal to, for example, the area of the upper surface of the support substrate SS.

FIGS. 4A to 4D are enlarged cross-sectional views illustrating an example of a part of a procedure of the manufacturing method of the support substrate SS according to the embodiment.

As illustrated in FIG. 4A, the substrate 70 such as a semiconductor substrate or a conductive substrate is prepared.

As illustrated in FIG. 4B, the insulating layer 61 is formed on the upper surface of the substrate 70. At this point, it is preferable to form the insulating layer 61 in such a manner as to cover not only the upper surface of the substrate 70 but also at least a part of the bevel of the substrate 70. As a result, the upper surface of the substrate 70 is sufficiently protected in various types of processing described later.

As illustrated in FIG. 4C, a plurality of recesses 61r penetrating the insulating layer 61 is formed.

As illustrated in FIG. 4D, the sacrificial layer 21 such as a semiconductor layer or a conductive layer is formed on the upper surface of the insulating layer 61. As a result, the semiconductor layer, the conductive layer, or the like is filled also in the plurality of recesses 61r formed in the insulating layer 61, and the plurality of plugs 22 is formed in the insulating layer 61.

As described above, the support substrate SS of the embodiment is manufactured.

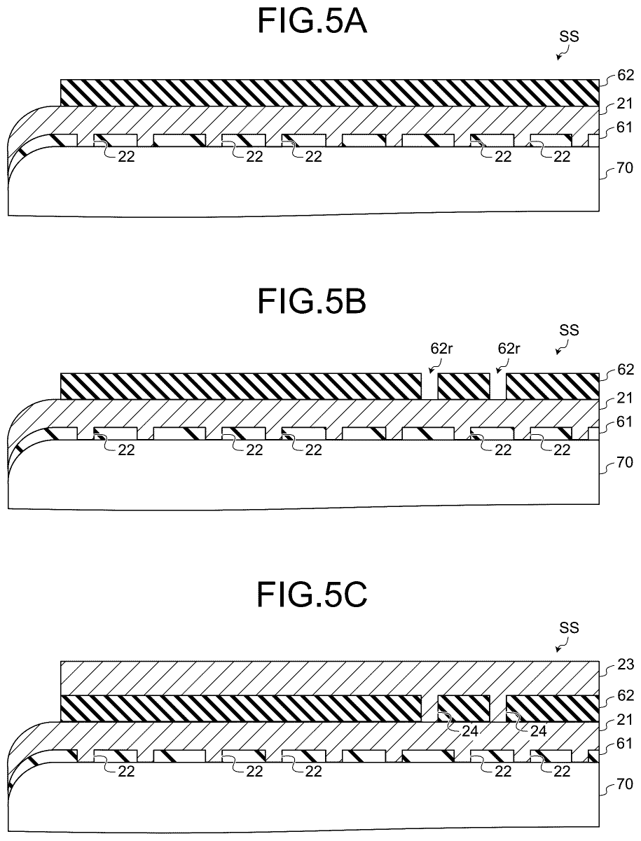

FIGS. 5A to 17B are cross-sectional views sequentially illustrating an example of a part of a procedure of the manufacturing method of the semiconductor storage device 1 according to the embodiment.

First, illustrated in FIGS. 5A to 5C are a state in which the support substrate SS is subjected to various types of processing. FIGS. 5A to 5C are enlarged cross-sectional views of the support substrate SS similarly to FIGS. 4A to 4D described above.

As illustrated in FIG. 5A, an insulating layer 62 as a second insulating layer is formed on the sacrificial layer 21 of the support substrate SS described above. The insulating layer 62 is a silicon oxide layer or the like having a high absorptivity of infrared rays or the like and has a layer thickness of, for example, within the range between 300 nm and 700 nm. Having the above layer thickness and being made of a material having high absorptivity of infrared rays and the like, the insulating layer 62 can be heated when irradiated with laser light having an infrared wavelength and thus can serve as a heat source.

As illustrated in FIG. 5B, the plurality of recesses 62r penetrating the insulating layer 62 is formed.

As illustrated in FIG. 5C, a base layer 23, as a second layer, having at least predetermined conductivity such as a semiconductor layer or a conductive layer is formed on the upper surface of the insulating layer 62. As a result, the semiconductor layer, the conductive layer, or the like is filled also in the plurality of recesses 62r formed in the insulating layer 62, and the plugs 24 as a plurality of second plugs are formed in the insulating layer 62. The layer thickness of the base layer 23 is, for example, within the range between 300 nm and 700 nm and is preferably formed to be thicker than the layer thickness of the sacrificial layer 21, for example.

As will be described in detail below, the base layer 23 serves as a base portion when the pillars PL and others are formed. Each of the plugs 24 has a columnar shape, for example, and electrically connects the base layer 23 and the sacrificial layer 21 arranged above and below the insulating layer 62.

The arrangement density of the plurality of plugs 24 in the insulating layer 62 is preferably smaller than the arrangement density of the plurality of plugs 22 in the insulating layer 61. That is, when viewed from the stacking direction of the insulating layer 62 and the base layer 23, the area of the plurality of plugs 24 is, for example, less than 50% of the area of an arrangement region of the insulating layer 62.

Note that, in the embodiment, at least a part of the insulating layer 62 formed on the support substrate SS, at least some of the plurality of plugs 24 in the insulating layer 62, and the base layer 23 are used as the insulating layer 60, the plugs PG, and the lower source line DSLa described above, respectively.

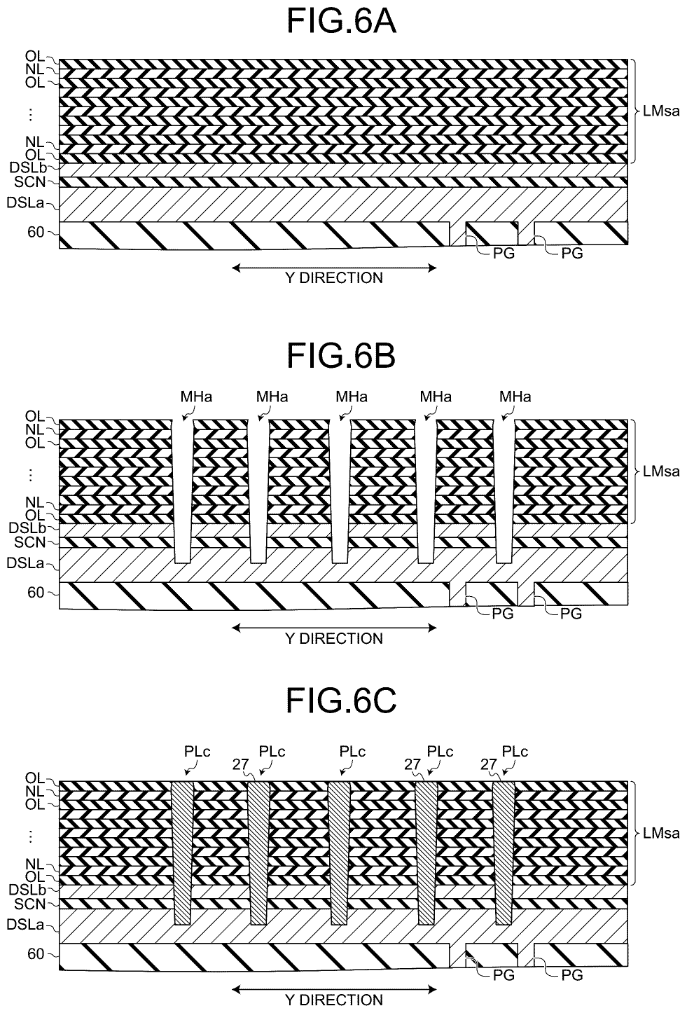

Next, a state in which pillars PL are formed in a region to be the memory region MR later is illustrated in FIGS. 6A to 8B. FIGS. 6A to 8B are diagrams each illustrating a cross section along the Y direction of the semiconductor storage device 1 during manufacture, including the region to be the memory region MR later.

In the following drawings, of the structure of the support substrate SS, a structure below the insulating layer 62 is omitted. In addition, hereinafter, the insulating layer 62, the plugs 24, and the base layer 23 described above are referred to as the insulating layer 60, the plugs PG, and the lower source line DSLa, respectively, constituting a part of the semiconductor storage device 1.

As illustrated in FIG. 6A, a middle sacrificial layer SCN and the upper source line DSLb are formed in this order on the lower source line DSLa formed on the insulating layer 62.

The lower source line DSLa and the upper source line DSLb are, for example, polysilicon layers. The middle sacrificial layer SCN is later replaced with a polysilicon layer or the like and becomes the middle source line BSL.

A stacked body LMsa in which insulating layers NL as a plurality of third insulating layers and the insulating layers OL as a plurality of fourth insulating layers are alternately stacked layer by layer is formed on the upper source line DSLb. The insulating layer NL is, for example, a silicon nitride layer or the like and functions as a sacrificial layer to be replaced with word lines WL or others later. The stacked body LMsa is a portion to be the stacked body LMa later by such replacement processing.

Note that, at this stage, the plurality of insulating layers OL including the uppermost insulating layer OL may have substantially the same thickness.

As illustrated in FIG. 6B, a plurality of memory holes MHa penetrating the stacked body LMsa, the upper source line DSLb, and the middle sacrificial layer SCN is formed using plasma etching or the like.

At this point, by using the lower source line DSLa as the stopper layer, the memory holes MH penetrating the middle sacrificial layer SCN and reaching the lower source line DSLa has a lower end in the lower source line DSLa.

As illustrated in FIG. 6C, the memory holes MHa are filled with a sacrificial layer 27 such as an amorphous silicon layer to form a plurality of pillars PLc.

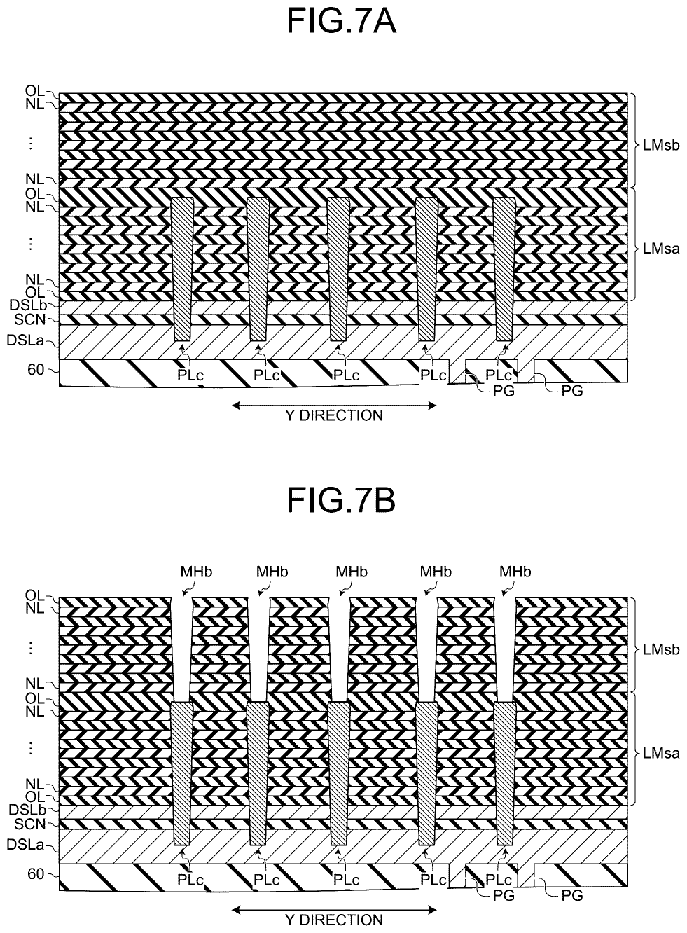

As illustrated in FIG. 7A, a silicon oxide layer and others are further stacked on the upper surface of the stacked body LMsa. As a result, the uppermost insulating layer OL of the stacked body LMsa becomes thicker than the other insulating layers OL. In addition, the upper ends of the pillars PLc are buried in the uppermost insulating layer OL.

In addition, a stacked body LMsb in which a plurality of insulating layers NL and a plurality of insulating layers OL are alternately stacked layer by layer is formed on the stacked body LMsa. The stacked body LMsb is to be the stacked body LMb with the insulating layers NL later replaced with word lines WL or others.

Note that, at this stage, the plurality of insulating layers OL of the stacked body LMsb including the uppermost insulating layer OL may have substantially the same thickness.

As illustrated in FIG. 7B, a plurality of memory holes MHb each penetrating the stacked body LMsb and reaching one of the upper ends of the plurality of pillars PLc arranged in the stacked body LMsa is formed by using plasma etching or the like. At this point, the sacrificial layers 27 included in these pillars PLc can be used as stopper layers.

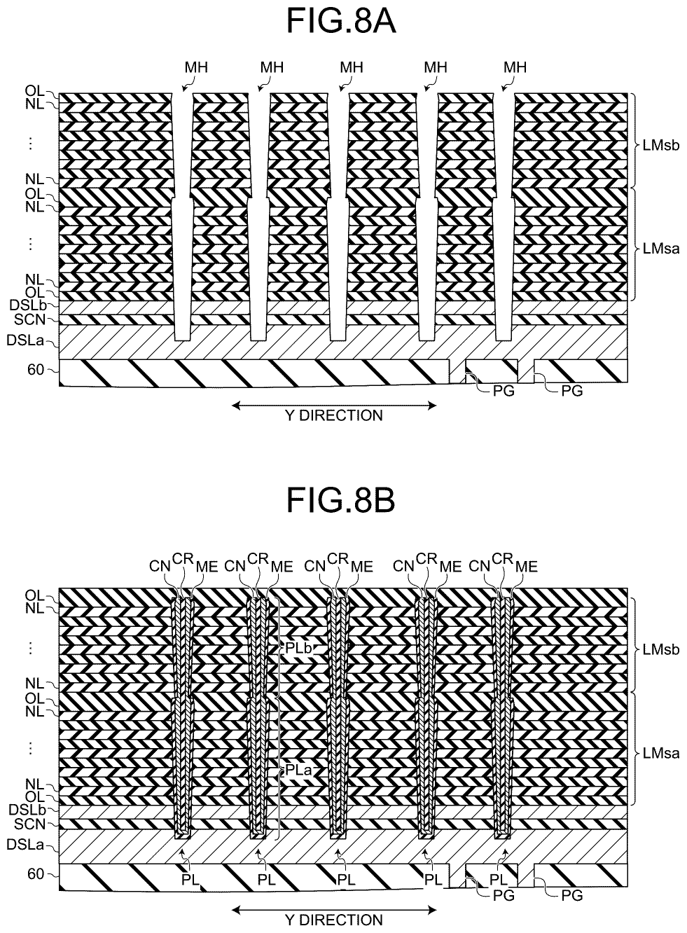

As illustrated in FIG. 8A, the sacrificial layers 27 are removed from the plurality of pillars PLc connected to the respective lower ends of the plurality of memory holes MHb. As a result, the plurality of memory holes MH penetrating the stacked bodies LMsa and LMsb and reaching the source line SL is formed.

As illustrated in FIG. 8B, a memory layer ME having a stacked structure of a block insulating layer BK, a charge accumulation layer CT, and a tunnel insulating layer TN (see FIG. 2B) is formed in each of the plurality of memory holes MH in an order from the outer circumferential side of the memory hole MH. In addition, a channel layer CN is formed on the side wall and the bottom surface of the plurality of memory holes MH via the memory layer ME. Furthermore, a gap in the memory hole MH on the inner side of the channel layer CN is filled with a silicon oxide layer or the like to form a core layer CR.

At this point, the memory layer ME, the channel layer CN, and the core layer CR are formed also on the upper surface of the stacked body LMsb. The memory layer ME, the channel layer CN, and the core layer CR are removed from the upper surface of the stacked body LMsb by etchback or the like.

As described above, the plurality of pillars PL is formed in the region to be the memory region MR later. However, at this point, the memory layers ME cover the entire side walls of the plurality of pillars PL, and the channel layers CN are not exposed.

In addition, a silicon oxide layer or the like is further stacked on the upper surface of the stacked body LMsb. As a result, the uppermost insulating layer OL of the stacked body LMsb becomes thicker than the other insulating layers OL. In addition, the upper ends of the pillars PL are buried in the uppermost insulating layer OL.

In this manner, for example, after the plurality of pillars PL is formed, a plurality of contact holes (not illustrated) extending in the stacking direction of the stacked bodies LMsa and LMb and reaching each of the plurality of insulating layers NL in the stacked bodies LMsa and LMb is formed in the region to be the contact region ER later. Alternatively, these contact holes may be formed after the stacked body LMsb is formed and before the plurality of memory holes MHb is formed.

After the contact holes are formed, a sacrificial layer such as an amorphous silicon layer is filled in the contact holes, thereby protecting the contact holes so as not to be affected by subsequent processing.

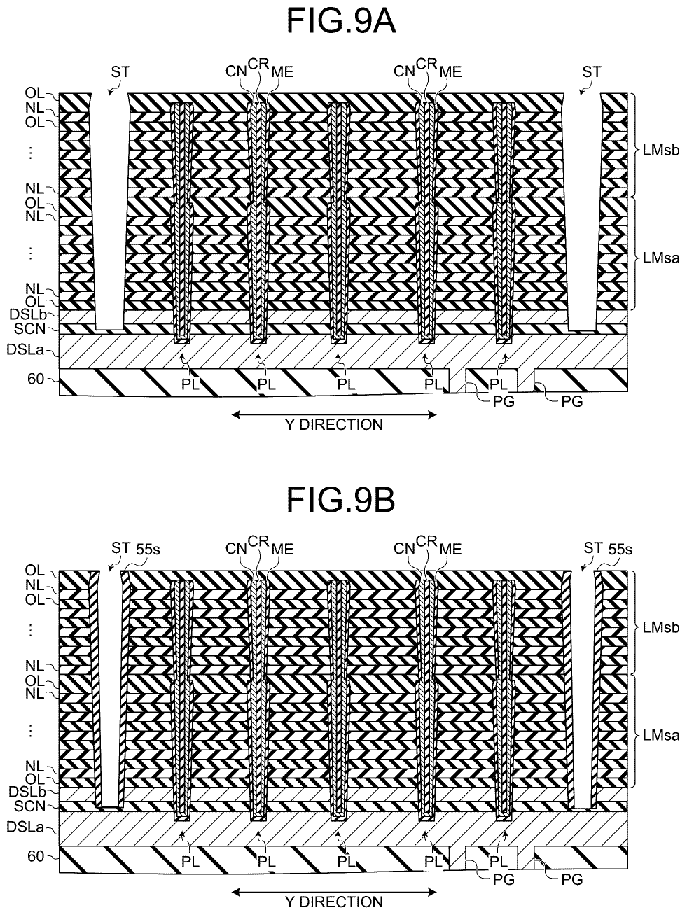

Next, a state in which the source line SL and the word lines WL are formed will be described with reference to FIGS. 9A to 13B. FIGS. 9A to 13B are cross-sectional views along the Y direction of the region to be the memory region MR later, similarly to FIGS. 6A to 8B described above.

As illustrated in FIG. 9A, slits ST that penetrates the stacked bodies LMsa and LMsb and the upper source line DSLb and reaches the middle sacrificial layer SCN are formed. The slits ST also extend in the X direction in the stacked bodies LMsa and LMsb, namely, in a direction perpendicular to the paper surface.

The slits ST are used for replacement processing described below and is to be the plate-shaped contacts LI later.

As illustrated in FIG. 9B, an insulating layer 55s is formed on the side walls of a slit ST facing each other in the Y direction. The insulating layer 55s is, for example, a silicon oxide layer or the like and is a temporary protective layer formed to protect the stacked bodies LMsa and LMsb in subsequent processing, unlike the above-described insulating layers 55 (see FIG. 2A) which the plate-shaped contacts LI will have on the side walls later.

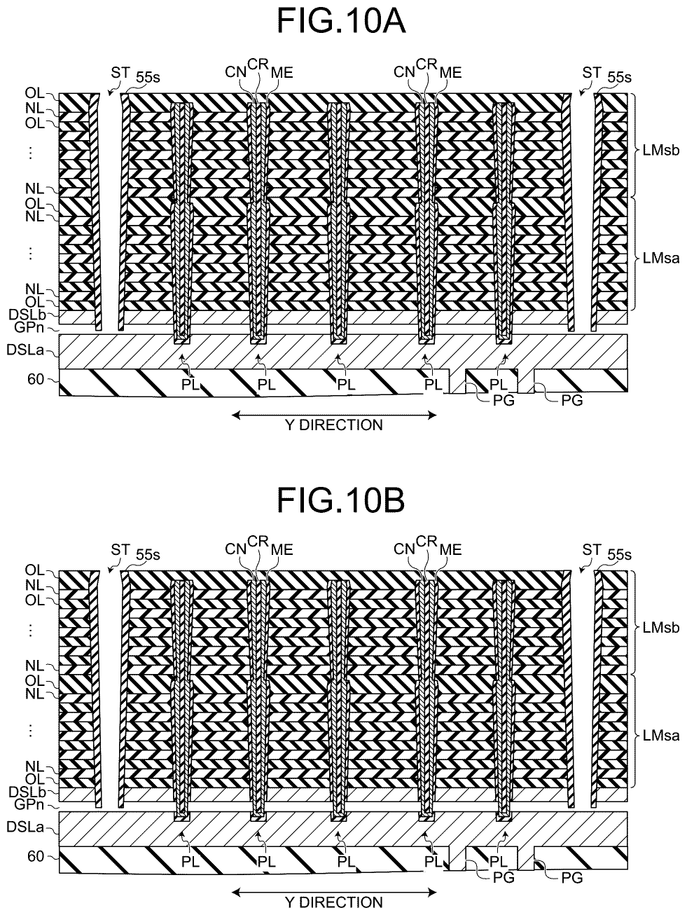

As illustrated in FIG. 10A, a removing liquid of the middle sacrificial layer SCN such as thermal phosphoric acid is caused to flow through the slits ST whose side walls are protected by the insulating layers 55s, whereby the middle sacrificial layer SCN sandwiched between the lower source line DSLa and the upper source line DSLb is removed.

As a result, a gap layer GPn is formed between the lower source line DSLa and the upper source line DSLb. Furthermore, a part of a memory layer ME in the outer peripheral portion of a pillar PL is exposed in the gap layer GPn.

At this point, since the side walls of the slits ST are protected by the insulating layers 55s, it is suppressed that the insulating layers NL in the stacked bodies LMsa and LMsb are also removed.

As illustrated in FIG. 10B, a chemical liquid is caused to flow into the gap layer GPn as appropriate through the slits ST, whereby the block insulating layers BK, the charge accumulation layers CT, and the tunnel insulating layers TN (see FIG. 2B) of the memory layers ME exposed in the gap layer GPn are sequentially removed. As a result, the memory layers ME are removed from parts of the side walls of the pillars PL, whereby parts of the channel layers CN on the inner side are exposed in the gap layer GPn.

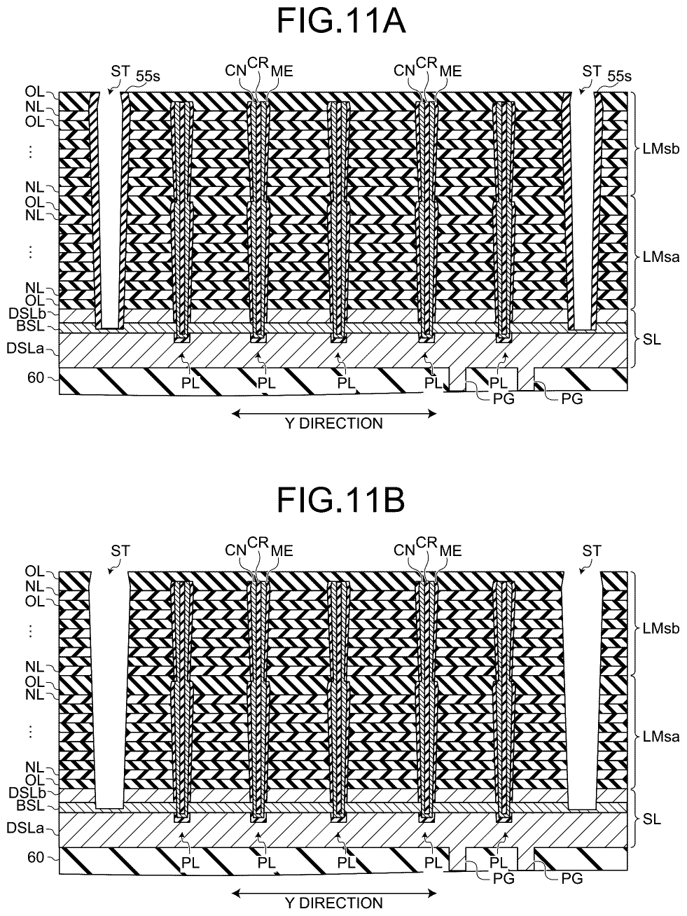

As illustrated in FIG. 11A, a source gas such as amorphous silicon is injected from the slits ST whose side walls are protected by the insulating layers 55s, whereby the gap layer GPn is filled with amorphous silicon or the like. In addition, the support substrate SS is heat-treated to make the amorphous silicon filled in the gap layer GPn to be polycrystalline, thereby forming the middle source line BSL containing polysilicon or the like.

As a result, the source line SL including the upper source line DSLb, the middle source line BSL, and the lower source line DSLa is formed. In addition, parts of the channel layers CN of the pillars PL are connected to the source line SL on the side surfaces via the middle source line BSL.

As illustrated in FIG. 11B, the insulating layers 55s are removed from the side walls of the slits ST.

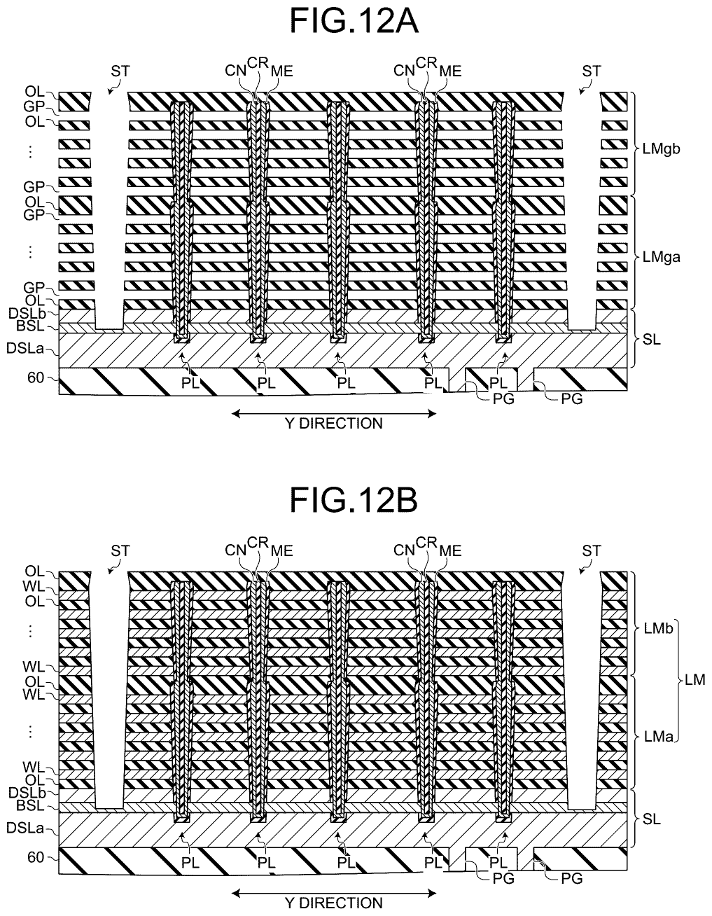

As illustrated in FIG. 12A, a removing liquid of the insulating layers NL such as thermal phosphoric acid is caused to flow from the slits ST into the stacked bodies LMsa and LMsb, thereby removing the insulating layers NL of the stacked bodies LMsa and LMsb. As a result, the stacked bodies LMga and LMgb, having a plurality of gap layers GP from which the insulating layers NL between the insulating layers OL are removed, are formed.

Note that the stacked bodies LMga and LMgb including the plurality of gap layers GP have a fragile structure. The plurality of pillars PL supports such fragile stacked bodies LMga and LMgb. As a result, the remaining insulating layers OL are prevented from warping, and the stacked bodies LMga and LMgb themselves are prevented from being distorted or collapsing.

As illustrated in FIG. 12B, a source gas of a conductive material such as tungsten or molybdenum is injected from the slits ST into the stacked bodies LMga and LMgb, whereby the gap layers GP of the stacked bodies LMga and LMgb are filled with the conductive material to form the plurality of word lines WL.

As a result, the stacked body LM including the stacked bodies LMa and LMb in which the plurality of word lines WL and the plurality of insulating layers OL are alternately stacked layer by layer is formed.

As described above, the processing of forming the middle source line BSL from the middle sacrificial layer SCN and the processing of forming the word lines WL from the insulating layers NL are also referred to as replacement processing.

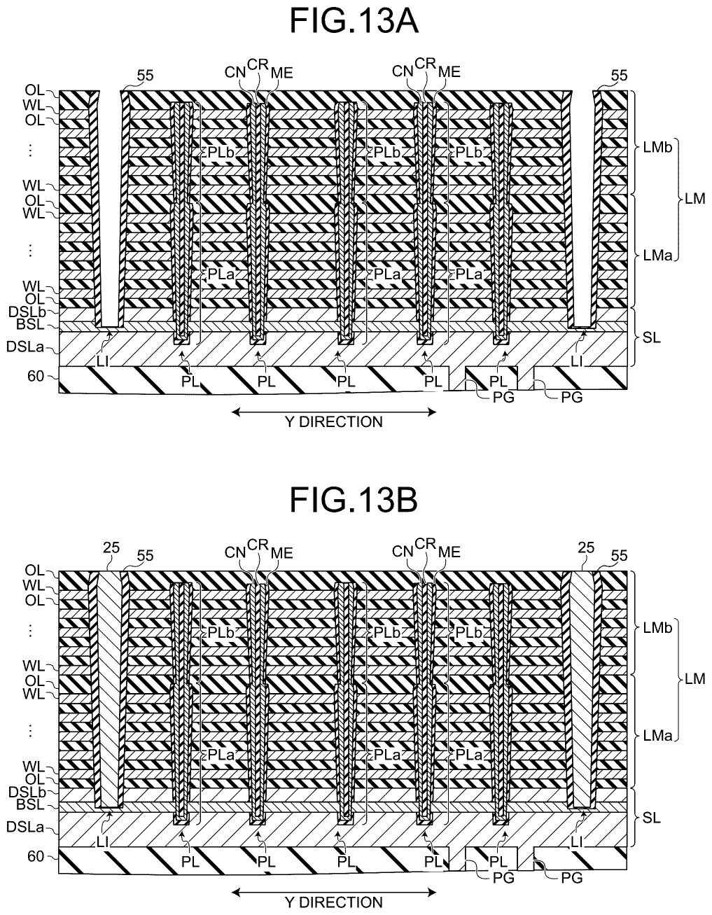

As illustrated in FIG. 13A, the insulating layers 55 are formed on the side walls of the slits ST.

As illustrated in FIG. 13B, the inside of an insulating layer 55 is filled with a conductive layer 25 to form a plate-shaped contact LI serving as a source line contact. However, an insulating layer 55 and the like may fill the slits ST without forming the conductive layers 25, whereby plate-like members not having a function as the source line contact may be formed.

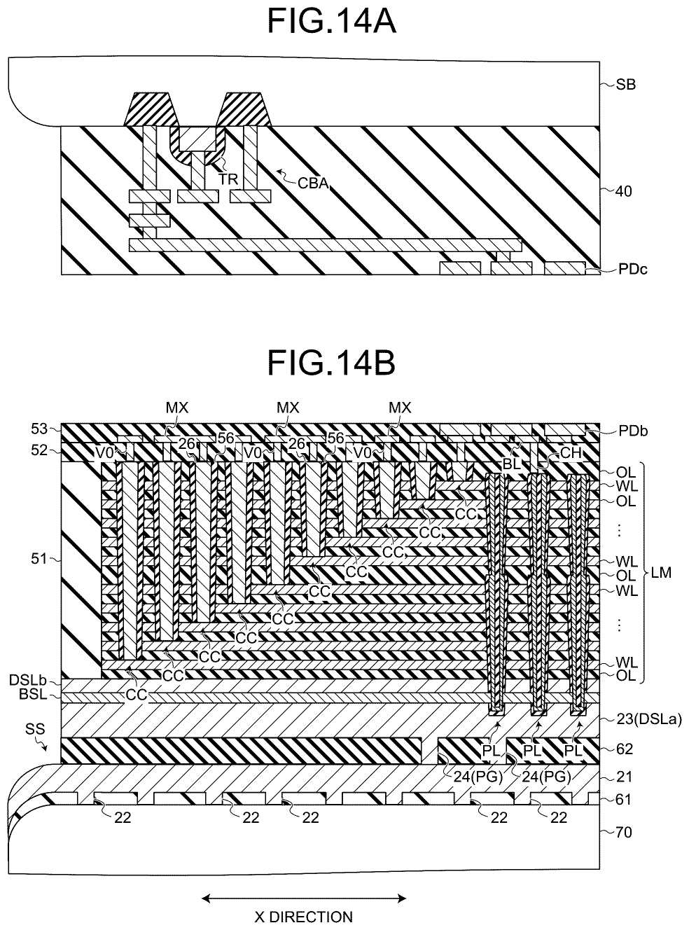

Next, with reference to FIGS. 14A to 17B, a state in which the support substrate SS on which the pillars PL and others are formed and the semiconductor substrate SB on which a peripheral circuit CBA and others are formed are bonded to each other will be described. FIGS. 14A to 17B are cross-sectional views along the X direction including parts of the support substrate SS on which the pillars PL and others are formed and the semiconductor substrate SB on which the peripheral circuit CBA and others are formed.

As illustrated in FIG. 14B, contacts CC each connected to one of the plurality of word lines WL are formed in the stacked body LM. Such a contact CC is formed by removing a sacrificial layer from the inside of a contact hole (not illustrated) after the processing of FIG. 13B and filling a conductive layer 26 in the contact hole in which an insulating layer 56 such as a silicon oxide layer is formed on sidewalls.

In addition, the insulating layers 52 and 53 are sequentially formed on the stacked body LM, a plug CH connected to a pillar PL and plugs V0 connected to the contacts CC are formed in the insulating layer 52, and a bit line BL and upper layer wiring MX connected to the plugs CH and V0, respectively, are formed in the insulating layer 53. Furthermore, electrode pads PDb connected to the bit line BL and the upper layer wiring MX is formed on the upper surface of the insulating layer 53.

Note that an insulating layer 51 having substantially the same thickness as that of the stacked body LM is formed outside the stacked body LM in which the plurality of contacts CC is arranged. The insulating layer 51 also constitutes a part of the above-described insulating layer 50 (see FIG. 1) together with the insulating layers 52 and 53.

As illustrated in FIG. 14A, the peripheral circuit CBA including a transistor TR is formed on a semiconductor substrate SB separate from the support substrate SS on which the pillars PL and others are formed. The peripheral circuit CBA is covered with the insulating layer 40, a contact, a via, wiring, and others are formed in the insulating layer 40, and the peripheral circuit CBA is electrically connected to an electrode pad PDc provided on a surface of the insulating layer 40.

In this manner, the surface of the semiconductor substrate SB, on which the peripheral circuit CBA and others are formed, on which the peripheral circuit CBA is provided is disposed to face the surface of the support substrate SS on which the pillars PL and others are provided.

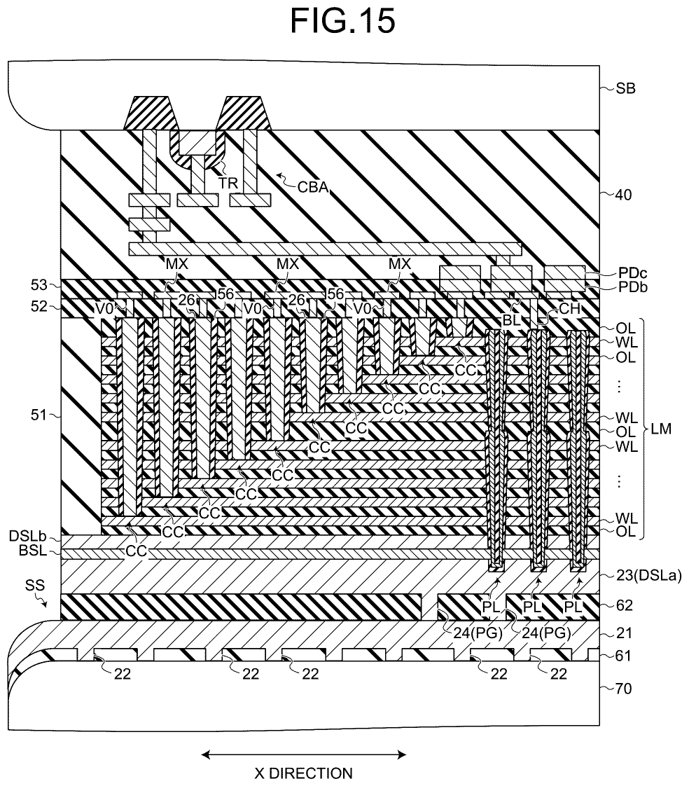

As illustrated in FIG. 15, the insulating layer 53 on the support substrate SS side and the insulating layer 40 on the semiconductor substrate SB side are bonded. These insulating layers 53 and 40 can be bonded by being activated in advance by, for example, plasma treatment or the like. When the insulating layers 53 and 40 are bonded, the support substrate SS and the semiconductor substrate SB are aligned in such a manner that the electrode pad PDb formed on the insulating layer 53 and the electrode pad PDc formed on the insulating layer 40 overlap each other.

After the insulating layers 53 and 40 are bonded, an annealing treatment is performed to bond the electrode pads PDb and PDc by, for example, Cu—Cu bonding. As a result, the support substrate SS and the semiconductor substrate SB are bonded together.

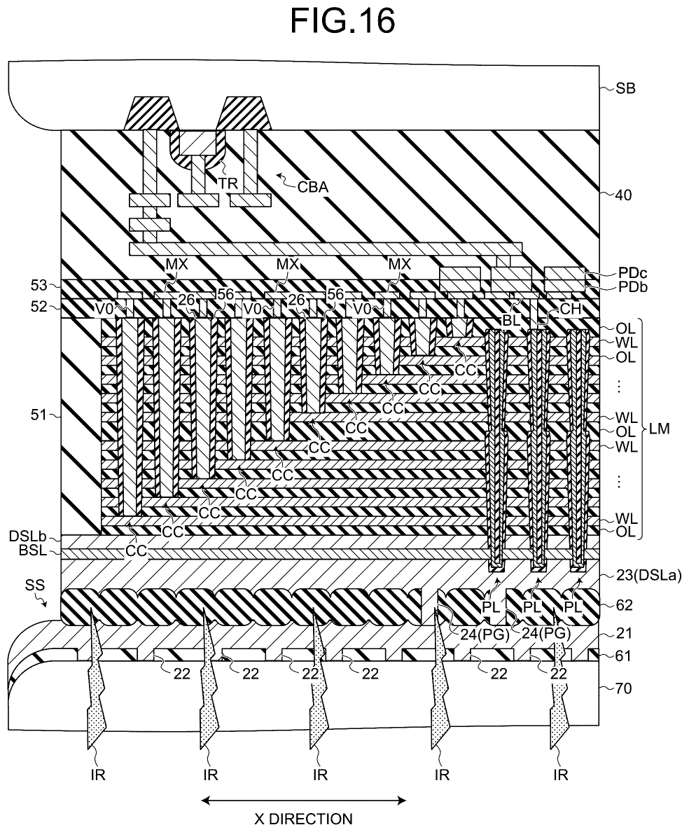

As illustrated in FIG. 16, laser light IR is emitted to the back surface side of the support substrate SS. The laser light IR may be infrared light having a wavelength such as 10 μm that is easily transmitted through a semiconductor layer, a metal layer, and the like and easily absorbed by the silicon oxide layer and the like. As a result, the laser light IR is absorbed by the insulating layer 62 formed on the support substrate SS, and the insulating layer 62 serves as a heat source to generate stress in the insulating layer 62.

Incidentally, the insulating layer 61 under the insulating layer 62 is also made of a similar material as that of the insulating layer 62. However, since the layer thickness of the insulating layer 61 is set to, for example, less than or equal to 100 nm, the insulating layer 61 is not heated to such an extent that stress is generated by the laser light IR.

In addition, crystal defects and the like are originally present in the base layer 23 and the sacrificial layer 21 formed above and below the insulating layer 62 serving as the heat source from the time of formation of these layers. Therefore, by heating the insulating layer 62, stress is also generated in the base layer 23 and the sacrificial layer 21, and for example, the roughness of a surface on a side in contact with the insulating layer 62 may be increased.

The stress of the sacrificial layer 21 may also be transmitted to the back surface side of the sacrificial layer 21. However, since such stress of the sacrificial layer 21 is absorbed by the insulating layer 61 formed on the back surface side of the sacrificial layer 21, the stress is suppressed from being transmitted to a surface of the substrate 70. In addition, since the base layer 23 is formed to be thicker than, for example, the sacrificial layer 21, the stress is suppressed from being transmitted to the surface side of the base layer 23, namely, the middle source line BSL or others in the upper layer.

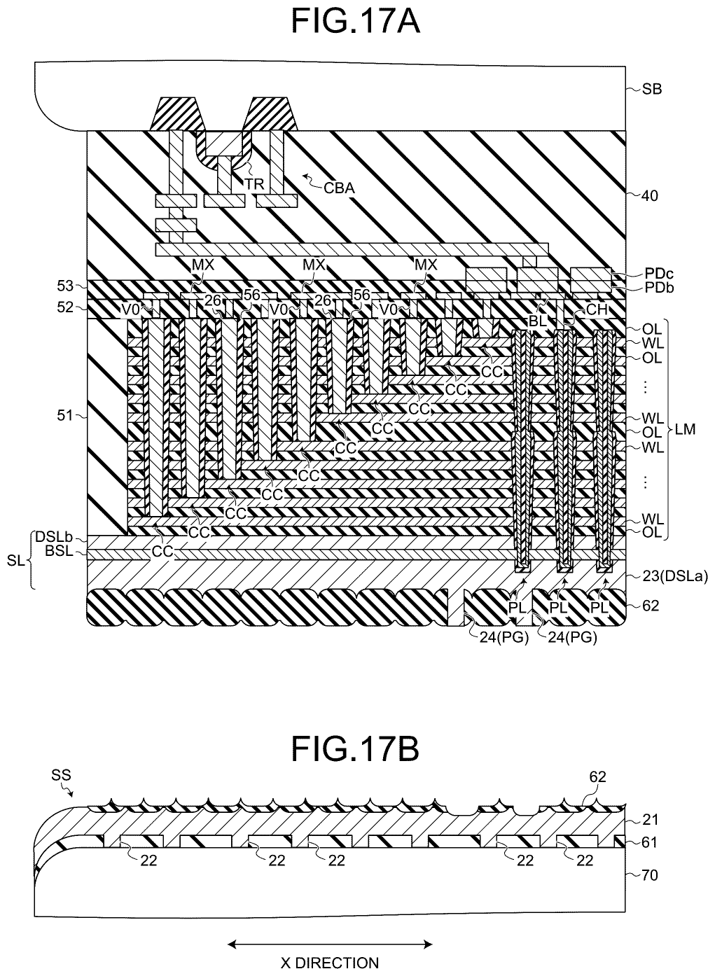

As illustrated in FIGS. 17A and 17B, the insulating layer 62 heated by the laser light IR is cleaved by the stress generated inside. As a result, the support substrate SS is peeled off from the semiconductor substrate SB including the stacked body LM in which the pillars PL and others are formed, the source line SL, the plugs PG, and others, and on which the peripheral circuit CBA is formed.

Thereafter, the insulating layer 62 exposed on the lower surface of the semiconductor substrate SB and including the plugs PG is planarized by chemical mechanical polishing (CMP) or the like, and an electrode film EL is formed and connected to the plugs PG.

As described above, the semiconductor storage device 1 according to the embodiment is manufactured.

Meanwhile, the support substrate SS side peeled off from the semiconductor substrate SB includes at least the insulating layer 61 and the sacrificial layer 21 in which the plurality of plugs 22 is formed. A part of the cleaved insulating layer 62 may be included on the support substrate SS side.

However, the sacrificial layer 21 of the support substrate SS is in a state in which the roughness of the surface is increased due to the stress of the insulating layer 62 heated by the laser light IR, and the surface is uneven. Moreover, since the plugs 24 (PG) have been pulled out from the support substrate SS side to the semiconductor storage device 1 side, the unevenness of the surface of the sacrificial layer 21 may be even more remarkable.

Such a used support substrate SS is subjected to reproduction processing described below and reused as a support substrate SS used for manufacture of a new semiconductor storage device 1.

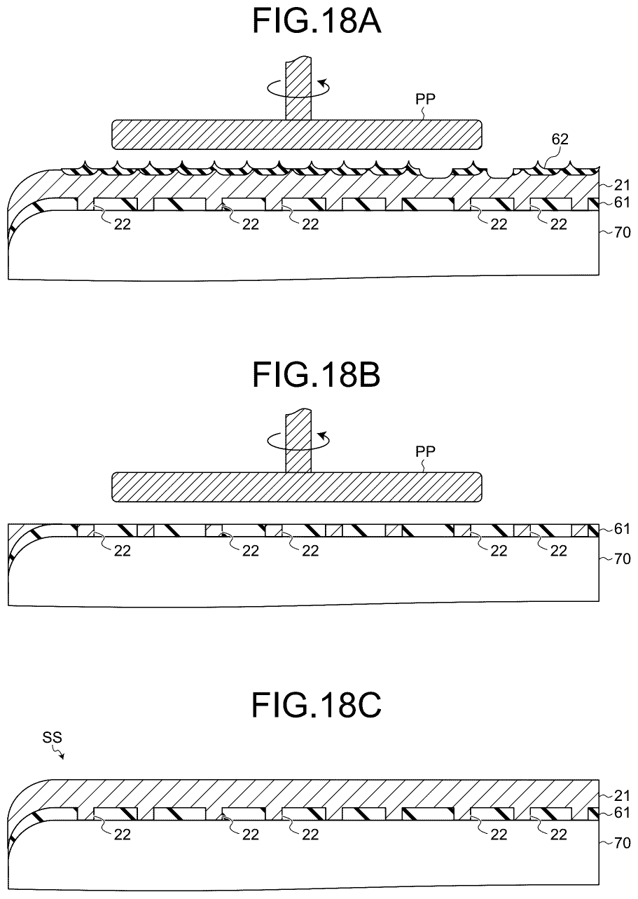

FIGS. 18A to 18C are cross-sectional views illustrating an example of a part of a procedure of reproduction processing of the support substrate SS according to the embodiment. Similarly to FIG. 17B described above, the drawings are cross-sectional views including a part of the support substrate SS having been peeled off from the structure including the pillars PL and others.

As illustrated in FIG. 18 A, the sacrificial layer 21 whose surface is uneven is ground by a polishing pad PP. At this point, the insulating layer 62 remaining on the surface of the sacrificial layer 21 may be removed in advance, as necessary.

As illustrated in FIG. 18B, by grinding the sacrificial layer 21 using the insulating layer 61 thereunder as a stopper layer, the sacrificial layer 21 is removed, and the insulating layer 61 is exposed thereunder in a state where the surface is planarized. The plurality of plugs 22 remain in the insulating layer 61.

As illustrated in FIG. 18C, a sacrificial layer 21 is newly formed on the upper surface of the insulating layer 61 including the plugs 22.

As a result, the support substrate SS that has been used is reproduced. The reproduction processing of the support substrate SS illustrated in FIGS. 18A to 18C above may also be included in the manufacturing method of the support substrate SS.

### Overview

A semiconductor storage device such as a three-dimensional nonvolatile memory may be manufactured by, for example, forming a stacked body including a plurality of pillars on a support substrate and bonding the support substrate to a semiconductor substrate on which a peripheral circuit is separately formed. The support substrate is bonded to the semiconductor substrate and then peeled off to be repeatedly reused. As the number of times of reuse of the support substrate increases, the manufacturing cost of the semiconductor storage device can be reduced more. However, when the support substrate is peeled off from the semiconductor substrate, the support substrate is worn as described below.

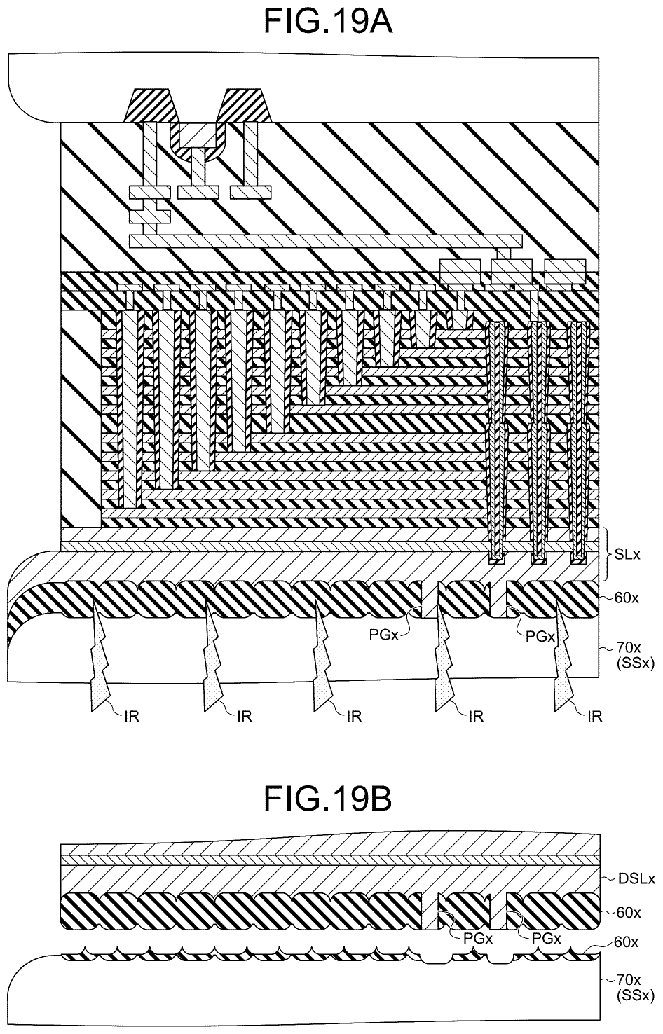

FIGS. 19A and 19B are partially enlarged cross-sectional views illustrating a state in which a support substrate SSx according to a comparative example is peeled off.

As illustrated in FIG. 19A, in a manufacturing method of a semiconductor storage device of the comparative example, a substrate 70x such as a semiconductor substrate is used as it is as the support substrate SSx. An insulating layer 60x in which a plurality of plugs PGx is formed and a source line SLx are formed on the support substrate SSx. The plurality of plugs PGx electrically connects the source line SLx and the support substrate SSx above and below the insulating layer 60x. A stacked body including a plurality of pillars, contacts, and others is formed further above the source line SLx, and a semiconductor substrate on which a peripheral circuit is formed is further bonded.

Incidentally, the pillars above the support substrate SSx is formed of a plurality of memory holes penetrating the stacked body in which different types of insulating layers are alternately stacked. The plurality of memory holes are formed by plasma etching or the like. The thickness of the stacked body ranges from several micrometers to several tens of micrometers, and plasma etching processing requires a long time. At this point, charges may be gradually accumulated in the plurality of insulating layers of the stacked body, and arcing may occur between the bottom surface of a memory hole being processed and the source line SLx or others.

As described above, by forming the plurality of plugs PGx electrically connecting the source line SLx and the support substrate SSx in the insulating layer 61, such charges can be released to the support substrate SSx side, whereby arcing is suppressed.

After being bonded to the semiconductor substrate, the back surface of the support substrate SSx is irradiated with laser light IR to heat the insulating layer 60x, thereby generating a stress in the insulating layer 60x. The source line SLx and the support substrate SSx above and below the insulating layer 60x both contain crystal defects and the like. Therefore, by heating the insulating layer 60x, stress is also generated in the source line SLx and the support substrate SSx, and unevenness is generated on the surfaces of the source line SLx and the support substrate SSx on the insulating layer 60x side.

As illustrated in FIG. 19B, the insulating layer 60x is cleaved by the stress generated inside, whereby the support substrate SSx is peeled off. At this point, the plugs PGx that suppress arcing are pulled out, whereby the unevenness of the surface of the support substrate SSx may be further deteriorated.

When the used support substrate SSx is reproduced, the unevenness of the surface of the support substrate SSx is removed by grinding. However, since such unevenness is generated on the surface of the support substrate SSx, the thickness of the support substrate SSx to be removed increases, and the wear amount of the support substrate SSx at one time of use increases. Therefore, the reusable number of times of the support substrate SSx decreases, and the manufacturing cost of the semiconductor storage device increases.

The support substrate SS according to the embodiment includes the substrate 70 having conductivity, the insulating layer 61 disposed on the substrate 70 and having a layer thickness of less than or equal to 100 nm, the sacrificial layer 21 having conductivity and disposed on the insulating layer 61, and the plurality of plugs 22 penetrating the insulating layer 61 and connecting the substrate 70 and the sacrificial layer 21.

By manufacturing the semiconductor storage device 1 by using such a support substrate SS by forming the stacked body LM including the pillars PL and others, the source line SL, the plugs PG, and others on the support substrate SS, it is possible to suppress wear of the support substrate SS.

That is, the stress, generated in the sacrificial layer 21 when the insulating layer 62 is cleaved using the laser light IR, is absorbed by the insulating layer 61 thereunder and is suppressed from reaching the substrate 70 further below the insulating layer 62. As a result, the wear of the support substrate SS can be suppressed, and the number of times that the support substrate SS can be reused can be increased. Therefore, the manufacturing cost of the semiconductor storage device 1 can be reduced.

Furthermore, the insulating layer 61 is set to be sufficiently thin, for example, less than or equal to 100 nm. Therefore, it is possible to suppress the insulating layer 61 from being heated and cleaved thereat when irradiated with the laser light IR.

According to the support substrate SS of the embodiment, the insulating layer 62 has a layer thickness of more than or equal to 300 nm. In this manner, by forming the insulating layer 62 sufficiently thick, the laser light IR can be efficiently absorbed, and the insulating layer 62 can be cleaved by stress due to heating.

According to the support substrate SS of the embodiment, the layer thickness of the sacrificial layer 21 is within the range between 300 nm and 700 nm. In this manner, by setting the sacrificial layer 21 to be thin, the material cost can be reduced, and the time required for manufacturing and reproducing the support substrate SS can be shortened.

Incidentally, for example, it is also possible to suppress the stress from being transmitted from the insulating layer 62 and the sacrificial layer 21 to the substrate 70 by forming a sufficiently thick sacrificial layer 21 directly on the substrate 70 by discarding the insulating layer 61 and the plugs 22. However, in this case, it is necessary to form the sacrificial layer 21 thick, whereby the material cost increases, and the time required for manufacturing and reproducing the support substrate SS may be prolonged.

As described above, by interposing the insulating layer 61 that absorbs stress between the sacrificial layer 21 and the substrate 70 and providing the plugs 22 in the insulating layer 61 to maintain electric conduction between the sacrificial layer 21 and the substrate 70, the sacrificial layer 21 can be made thin, which makes it possible to more easily suppress wear of the substrate 70 due to the stress while suppressing arcing.

That is, the plugs 24 electrically connecting the source line SL and the sacrificial layer 21 and the plugs 22 electrically connecting the sacrificial layer 21 and the substrate 70 are included between the source line SL and others and the substrate 70. As described above, since the plugs 24, the sacrificial layer 21, and the plugs 22 serve as current paths from the source line SL to the substrate 70, arcing during plasma etching can be suppressed.

According to the support substrate SS of the embodiment, the area of the plurality of plugs 22 is greater than or equal to 50% of the area of the arrangement region of the insulating layer 61 when viewed from the stacking direction of the insulating layer 61 and the sacrificial layer 21. As described above, by increasing the area of the plurality of plugs 22 in the insulating layer 61, it becomes easier to release the charges during plasma etching to the substrate 70 side, and the arcing can be more reliably suppressed.

According to the support substrate SS of the embodiment, the arrangement density of the plurality of plugs 22 in the insulating layer 61 is higher than the arrangement density of the plurality of plugs 24 in the insulating layer 62.

The plurality of plugs 24 is arranged at positions closer to the structure of the semiconductor storage device 1 such as the pillars PL. As described above, for example, by sufficiently lowering the arrangement density of the plurality of plugs 24 as compared with the plurality of plugs 22, it becomes easier to arrange the plugs 22 while avoiding interference with various structures of the semiconductor storage device 1.

### Modifications

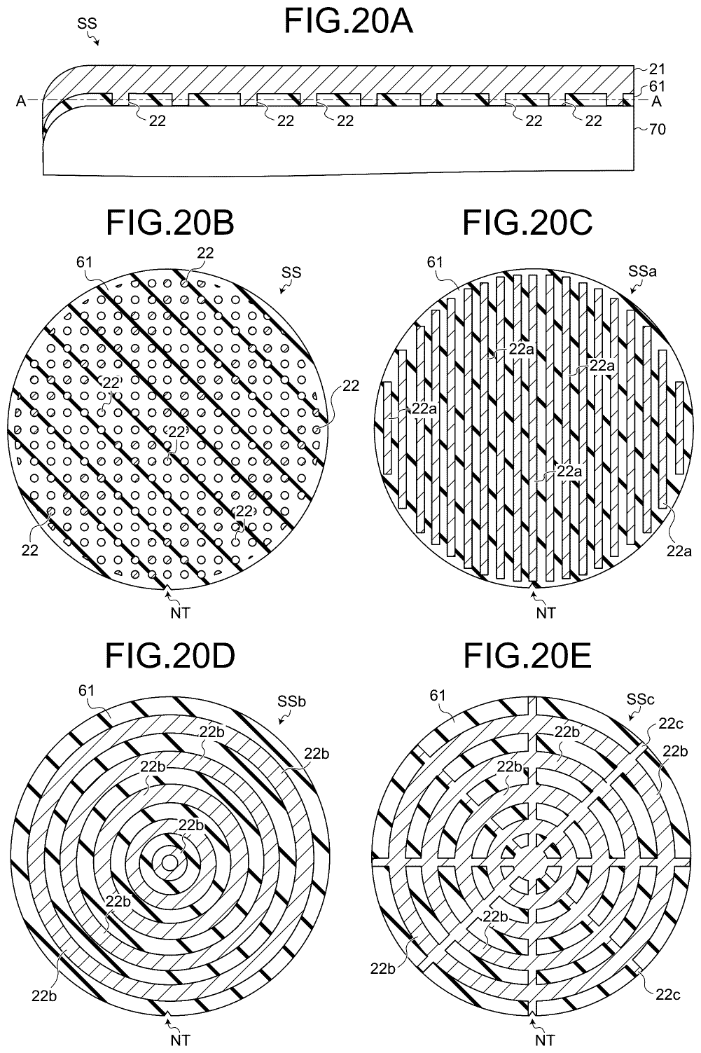

In the above-described embodiment, the plugs 22 and 24 of the support substrate SS have columnar shapes, for example. However, the plugs 22 and 24 of the support substrate SS may have other shapes. For example, the plugs 24 have a high degree of freedom in terms of its number of items, the arrangement, the shape, and others, and various arrangements, shapes, and others can be adopted. Hereinafter, some examples are illustrated in FIGS. 20A to 20E.

FIGS. 20A to 20E are diagrams illustrating examples of structures of the plugs 22 and 22a to 22c of the support substrates SS and SSa to SSc, respectively, according to the embodiment and modifications of the embodiment. FIG. 20A is a partially enlarged cross-sectional view of the support substrate SS, similarly to FIG. 3B and others described above. FIGS. 20B to 20E are cross-sectional views taken along line A-A of FIG. 20A of the support substrates SS and SSa to SSc according to the embodiment and the modifications.

As described above, the support substrate SS of the embodiment illustrated in FIG. 20B includes a plurality of plugs 22 having the columnar shape, for example. In the example of FIG. 20B, the plurality of plugs 22 is arranged in a grid shape in the insulating layer 61 when viewed from the stacking direction of the insulating layer 61, the sacrificial layer 21, and others. However, the arrangement of the plurality of plugs 22 is not limited to the grid shape and may be, for example, a zigzag shape or the like.

The support substrate SSa of a modification illustrated in FIG. 20C includes a plurality of plugs 22a each having a line shape, for example. In the example of FIG. 20C, the plurality of plugs 22a extend in the insulating layer 61 in the vertical direction of the support substrate SSa, for example, with a notch NT of the support substrate SSa facing downward.

In the case of adopting the structure of the support substrate SSa, for example, by making the line width of the plurality of plugs 22a equal to a space width between the plurality of plugs 22a, the area of the plurality of plugs 22 can be set to 50% of the area of the arrangement region of the insulating layer 61.

Furthermore, by setting the line width>the space width, the area of the plurality of plugs 22 can be set to more than 50% of the area of the arrangement region of the insulating layer 61.

Note that the direction in which the plugs 22a having the line shape extend is not limited to the example of FIG. 20C and may be the horizontal direction of the support substrate SSa with the notch NT facing downward, a direction inclined with respect to the vertical and horizontal directions, or like.

The support substrate SSb of a modification illustrated in FIG. 20D includes, for example, a plurality of plugs 22b each having an annular shape. In the example of FIG. 20D, the plurality of annular plugs 22b, extending concentrically from the center point of the support substrate SSb when viewed from the stacking direction of the insulating layer 61, the sacrificial layer 21, and others, is arranged.

In the support substrate SSb of a modification illustrated in FIG. 20E, for example, a plurality of plugs 22c radially extending from the center of the support substrate SSc is arranged in addition to the plurality of plugs 22b each having an annular shape.

Note that, in any case of FIGS. 20B to 20E described above, the pluralities of plugs 22 and 22a to 22c are preferably arranged in a substantially uniformly dispersed manner in the insulating layer 61 of the support substrates SS and SSa to SSc, respectively.

### Other Modifications

In the above-described embodiment and modifications, the base layer 23 serving as a base portion when the pillars PL and others are formed, the plugs 24 that establishes electric conduction between the base layer 23 and the sacrificial layer 21, and others are used also as a part of the structure of the semiconductor storage device 1. However, the base layer 23, the plugs 24, and others may be used exclusively as the basic portion of the pillars PL, which is the original purpose, and as a part of current paths to the substrate 70.

In this case, the base layer 23 and the plugs 24 remaining on the pillars PL side due to peeling off of the support substrate SS may be removed by grinding, for example. In addition, at the time of removal by grinding of the base layer 23 and the plugs 24, the grinding processing may be continued until the channel layers CN at the lower ends of the pillars PL are exposed, and a source line and others connected to the channel layers CN exposed at the lower ends of the pillars PL may be newly formed.

In addition, in the embodiment and the modifications described above, the insulating layers NL and OL are stacked twice separately, and the stacked body LM having a two-tier structure including the stacked bodies LMa and LMb is provided. However, the stacked body may have a one-tier structure or a structure of three or more tiers. By increasing the number of tiers, the number of stacked layers of word lines WL can be further increased.

In addition, in the above-described embodiment and modifications, the contact regions ER are arranged at both ends in the X direction of the stacked body LM. However, the arrangement positions of the contact regions ER in the stacked body LM are not limited thereto. The contact region ER may be arranged, for example, in the central portion of the stacked body LM, and in this case, for example, the memory region MR can be arranged at both ends of the stacked body LM.

In addition, in the above-described embodiment and modifications, the support substrates SS and SSa to SSc are used for manufacture of the semiconductor storage device 1 using substrate bonding technology. However, the manufacturing process and the like in which the support substrates SS and SSa to SSc can be used are not limited to the case of manufacturing the semiconductor storage device 1 described above but can also be applied to manufacturing processes of various semiconductor devices.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A support substrate comprising:
a substrate having conductivity;
a first insulating layer disposed on the substrate;
a first layer having conductivity and disposed on the first insulating layer;
a second insulating layer disposed on the first layer;
a second layer having conductivity and disposed on the second insulating layer;
a plurality of first plugs penetrating the first insulating layer and connecting the substrate and the first layer; and
a plurality of second plugs penetrating the second insulating layer and connecting the first layer and the second layer.

2. The support substrate according to claim 1, wherein
the second layer serves as a base layer in which at least a part of a structure of a semiconductor device is formed at a time of manufacturing the semiconductor device, and
the second layer is peeled off from the substrate by causing the second insulating layer to cleave by irradiation with laser light.

3. The support substrate according to claim 2, wherein
a layer thickness of the first insulating layer is less than or equal to 100 nm, and
a layer thickness of the second insulating layer is more than or equal to 300 nm.

4. The support substrate according to claim 1, further comprising:
on the second layer, a plurality of memory pillars connected to the second layer.

5. The support substrate according to claim 4,
wherein a layer thickness of the second layer is within a range between 300 nm and 700 nm.

6. The support substrate according to claim 4,
wherein an arrangement density of the plurality of first plugs in the first insulating layer is higher than an arrangement density of the plurality of second plugs in the second insulating layer.

7. The support substrate according to claim 4, further comprising:
a peripheral circuit disposed on a semiconductor substrate and covered with a third insulating layer, wherein
the plurality of memory pillars are covered with a fourth insulating layer, and
the semiconductor substrate and the substrate are bonded at the third insulating layer and the fourth insulating layer.

8. A support substrate comprising:
a substrate having conductivity;
a first insulating layer disposed on the substrate and having a layer thickness of less than or equal to 100 nm;
a first layer having conductivity and disposed on the first insulating layer; and
a plurality of first plugs penetrating the first insulating layer and connecting the substrate and the first layer.

9. The support substrate according to claim 8,
wherein an area of the plurality of first plugs is greater than or equal to 50% of an area of an arrangement region of the first insulating layer when viewed from a stacking direction of the first insulating layer and the first layer.

10. The support substrate according to claim 8,
wherein each of the plurality of first plugs has at least one of a columnar shape, a line shape, or an annular shape.

11. A manufacturing method of a support substrate, the method comprising:
forming a first insulating layer having a layer thickness of less than or equal to 100 nm on a substrate having conductivity;
forming a plurality of first plugs penetrating the first insulating layer and connected to the substrate; and
forming a first layer having conductivity on the first insulating layer and connecting the first layer with the plurality of first plugs.

12. The manufacturing method of a support substrate according to claim 11, the method further comprising:
forming a second insulating layer on the first layer;
forming a plurality of second plugs penetrating the second insulating layer and connected to the first layer; and
forming, on the second insulating layer, a second layer connected to the second plugs and having conductivity.

13. The manufacturing method of a support substrate according to claim 12, the method further comprising:
forming, on the second layer, a plurality of memory pillars connected to the second layer;
peeling off the second layer on which the plurality of memory pillars is formed from the substrate side by irradiating the second insulating layer with laser light from a back surface side of the substrate to cause the second insulating layer to cleave; and
reproducing the support substrate by polishing a surface of the substrate from which the second layer has been peeled off and exposing the first insulating layer on which the first plugs are formed.

14. The manufacturing method of a support substrate according to claim 13, wherein
a layer thickness of the first insulating layer is set to less than or equal to 100 nm, and
a layer thickness of the second insulating layer is set to more than or equal to 300 nm.

15. The manufacturing method of a support substrate according to claim 14, the method further comprising:
setting an arrangement density of the plurality of first plugs in the first insulating layer to be higher than an arrangement density of the plurality of second plugs in the second insulating layer, and
forming the plurality of memory pillars in such a manner as to penetrate a stacked body by plasma etching using the second layer as a stopper layer, the stacked body including a plurality of third insulating layers and a plurality of fourth insulating layers alternately stacked layer by layer.

16. A manufacturing method of a semiconductor storage device, the method comprising:
preparing a substrate on which a first insulating layer and a first layer having conductivity are formed in this order, the substrate having conductivity and provided with a plurality of first plugs penetrating the first insulating layer and connecting the substrate and the first layer;
forming a second insulating layer on the first layer;
forming a plurality of second plugs penetrating the second insulating layer and connected to the first layer;
forming, on the second insulating layer, a second layer connected to the second plugs and having conductivity; and
forming, on the second layer, a plurality of memory pillars connected to the second layer.

17. The manufacturing method of a semiconductor storage device according to claim 16, the method further comprising:
peeling off the second layer on which the plurality of memory pillars is formed from the substrate side by irradiating the second insulating layer with laser light from a back surface side of the substrate to cause the second insulating layer to cleave.

18. The manufacturing method of a semiconductor storage device according to claim 17, wherein
a layer thickness of the first insulating layer is set to less than or equal to 100 nm, and
a layer thickness of the second insulating layer is set to more than or equal to 300 nm.

19. The manufacturing method of a semiconductor storage device according to claim 16, the method further comprising:
setting a layer thickness of the second layer to within a range between 300 nm and 700 nm; and
forming the plurality of memory pillars in such a manner as to penetrate a stacked body by plasma etching using the second layer as a stopper layer, the stacked body including a plurality of third insulating layers and a plurality of fourth insulating layers alternately stacked layer by layer.

20. The manufacturing method of a semiconductor storage device according to claim 19,
wherein an arrangement density of the plurality of first plugs in the first insulating layer is set to be higher than an arrangement density of the plurality of second plugs in the second insulating layer.
